(19) United States
(12) Patent Application Publication
(10) Pub. No.: US 2015/0162172 A1
(43) Pub. Date: Jun. 11, 2015

(54) MODIFIED TUNGSTEN-TITANIUM SPUTTERING TARGETS

(71) Applicants: CHI-FUNG LO, FORT LEE, NJ (US); PAUL GILMAN, SUFFERN, NY (US)

(72) Inventors: CHI-FUNG LO, FORT LEE, NJ (US); PAUL GILMAN, SUFFERN, NY (US)

(21) Appl. No.: 14/561,977

(22) Filed: Dec. 5, 2014

Related U.S. Application Data
(60) Provisional application No. 61/912,330, filed on Dec. 5, 2013.

(51) Int. Cl. H01J 37/34

(52) U.S. Cl. CPC H01J 37/3426

(57) ABSTRACT

A novel WTi target is described as having a Ti particle size similar to that of the W particle size. The target also contains controlled microstructural multi-phases characterized by an absence of a β (titanium-tungsten) alloy lamellar phase structure. The combination of controlled microstructural phases and controlled particle size improves overall sputtering performance whereby the sputtered face reduces formation of nodules which can flake off and deposit onto the resultant film to produce film defects during sputtering.

### CROSS REFERENCE TO RELATED APPLICATIONS

The present application claims priority from U.S. Application Ser. No. 61/912,330, filed Dec. 5, 2013, which is incorporated by reference herein in its entirety.

### FIELD OF INVENTION

The present invention relates to novel and improved tungsten-titanium sputtering targets. Particularly, the invention relates to tungsten-titanium sputtering target assemblies configured to reduce or eliminate particle generation into TiW films.

### BACKGROUND OF THE INVENTION

Tungsten-titanium (WTi) films are typically deposited onto a wafer as thin films which are known to act as an effective diffusion barrier in semiconductor applications. WTi deposited films are utilized for many applications, including by way of example, interconnect metallization in semiconductors, microelectromechanical systems (MEMS), photovoltaics and light emitting diodes (LEDs). In addition to being an effective diffusion barrier, the WTi films are known to provide adhesiveness and suitable properties as a capping layer.

WTi films are also recognized for their widespread applicability in a process called Controlled Collapse Chip Connection (C4), as shown in FIG. 1. The C4 process is a technology for advanced packaging of microelectric circuits. The process allows attachment of a bare chip to a packaging substrate in a face-down configuration, with electrical connections between the chip and the substrate via conducting “bumps”. The W—Ti film behaves as a passive barrier that remains adhesive when interposed between aluminum or tungsten and silicon. The barrier prevents the underlying copper shown in FIG. 1 from diffusing upwards. Barrier performance is further enhanced when the W—Ti layer is created by reactive sputtering in the presence of nitrogen or by exposing the deposited film to air.

The properties of WTi film can counteract the tendency for migration of copper on the wafer. Additionally, the WTi film remains stable on the wafer and serves as an adhesive layer. The need for WTi films continues to increase, particularly in view of the copper metallization required on today's chips.

The WTi films are typically formed by physical vapor deposition through plasma sputtering of a WTi target. However, WTi targets are known to generate an unacceptably high amount of particles when deposited as a film or layer, whereby particle emission from the target into the film or layer occurs during sputtering. The particle emission is believed to occur as a result of differing rates of W and Ti sputtering. FIG. 2 shows a representative wafer defect caused by particle generation on the film deposited during sputtering of a target. The defect is large and non-conducting such that it opens up three wires in the circuit. FIG. 3 shows another type of wafer defect caused by particle generation on the film deposited during sputtering of a target. The particles generated in the sputtered film causes a short. The defect of FIG. 3 is large and conducting such that it shorts out four wires on the circuit. These particles generated during sputtering contaminate the thin film and thus negatively affect the reliability and productivity of the thin film generated from sputtering of the WTi target. The resulting film defects cause manufacturing yield losses.

In view of the particle generation problems during sputtering of WTi targets, there has been considerable interest in evaluating causes of particulate generation during the sputtering of W—Ti targets and minimizing target particulate emission. Despite such design modifications, the problem of particle generation remains prevalent.

In view of the drawbacks currently available with WTi sputter targets, there is a growing need for improved WTi targets that can significantly reduce or eliminate the occurrence of particle generation during sputtering of WTi targets.

### SUMMARY OF THE INVENTION

The invention may include any of the following aspects in various combinations and may also include any other aspect of the present invention described below in the written description. In a first aspect, a sputtering target comprising: a solidified target comprising consolidated titanium particles in a composition ranging between about 5-15 wt % and a balance of consolidated tungsten, said target having a microstructure consisting essentially of a tungsten phase interdispersed with a titanium phase and further characterized by substantially no β (titanium-tungsten) alloy lamellar phase based on microstructure; said titanium powder particles characterized by a first particle size distribution having a particle size no greater than 20 microns, and said tungsten powder particles characterized by a second particle size distribution, wherein the first particle size is matched to the second particle size such that a difference between a median particle size of the titanium particles and a median particle size of the tungsten particles is about 15 microns or less; wherein said target is characterized by a substantial reduction or absence of nodule formation visually observed during sputtering in comparison to a conventional consolidated tungsten-titanium target without particle size matching.

In a second aspect of the invention, a titanium-tungsten sputtering target configured to be sputtered to produce improved titanium-tungsten films having reduced in-film particle defects, comprising: a solidified target comprising consolidated titanium powder particles in a compositional range of said target between about 5-15 wt % titanium based on a total weight of the solidified target and a balance of consolidated tungsten powder particles, said target having a microstructure consisting essentially of a tungsten phase continuously interdispersed with a titanium phase and further characterized by substantially no β (titanium-tungsten) alloy lamellar phase based on microstructure; said titanium powder particles characterized by a first particle size distribution having a first median size and further wherein the number of titanium particles per 200 micrometer square unit area of the target prior to sputtering is between about 50 to about 200; said tungsten powder particles characterized by a second particle size distribution having a second median size, the first particle size distribution matched with the second particle size distribution such that a difference between the first and the second median particle sizes is about 15 microns or less.

In a third aspect of the invention, a sputtering target comprising: a solidified target comprising consolidated titanium particles in a compositional range of said target between about 5-15 wt % based on a total weight of the solidified target, and a balance of consolidated tungsten powder particles, said target having a titanium characterized by the absence of hydrogenation; said solidified target having a multi-phase microstructure consisting essentially of a tungsten phase continuously interdispersed with a titanium phase, wherein said multi-phase microstructure is further characterized by substantially no β (titanium-tungsten) alloy laminar phase based on microstructure, said titanium powder particles characterized by a first particle size distribution of 5-20 microns and said tungsten powder particles characterized by a second particle size distribution of 3-10 microns, wherein the titanium powder particles are matched with the tungsten powder particles to a degree such that a difference between a median particle size of titanium and a median particle size of tungsten is about 15 microns or less; wherein said target is configured to be sputtered so as to form a sputter target face having a substantial reduction or elimination of nodules visually observed during sputtering in comparison to a conventional titanium-tungsten sputtering target without particle size matching, thereby reducing or eliminating particle generation onto TiW films produced from sputtering said sputtering target.

Other aspects, features and embodiments of the disclosure will be more fully apparent from the ensuing description and appended claims.

### BRIEF DESCRIPTION OF THE DRAWINGS

The objectives and advantages of the invention will be better understood from the following detailed description of the preferred embodiments thereof in connection with the accompanying figures wherein like numbers denote same features throughout and wherein:

FIG. 1 shows a solder bump process for which WTi is utilized as a diffusion barrier and adhesion layer;

FIG. 2 shows a representative wafer defect caused by particle generation on the film deposited during sputtering of a conventional target;

FIG. 3 shows another type of wafer defect caused by particle generation on the film deposited during sputtering of a conventional target;

FIG. 4 shows a typical Ti particle size distribution utilized in the production of a conventional WTi target;

FIG. 5 shows a narrower and smaller Ti powder distribution in comparison to that of FIG. 4 that is utilized in the production of the WTi target of the present invention;

FIG. 6 is an exemplary SEM microstructure of the inventive WTi in accordance with the principles of the present invention;

FIG. 7 shows nodules formed on a conventional TiW sputtered surface; and

FIG. 8 shows nodules along the sputtering face of a conventional target which have a tendency to generate particles on the sputtered film;

FIG. 9 shows a conventional WTi target having nodules along the sputter face; and

FIG. 10 shows a WTi target of the present invention showing a substantial reduction of nodules along the sputter face in comparison to the conventional WTi target of FIG. 9.

### DETAILED DESCRIPTION OF THE INVENTION

The disclosure is set out herein in various embodiments, and with reference to various features and aspects of the invention. The disclosure contemplates such features, aspects and embodiments in various permutations and combinations, as being within the scope of the disclosure. The disclosure may therefore be specified as comprising, consisting or consisting essentially of, any of such combinations and permutations of these specific features, aspects and embodiments, or a selected one or ones thereof.

Unless indicated otherwise, all percentages are expressed herein as wt % based on the total weight of target. The terms “micron” and “micrometers” are intended to be used interchangeably herein and have the same meaning.

The present invention has the ability to produce a WTi target having a controlled microstructure. In particular, the present invention contains a WTi target characterized by a reduction or absence of a beta (Ti, W) alloy laminar phase. The present invention avoids such brittle single phases which can cause increased hardness. As such, the invention is based, on a microstructure containing a selected Ti phase and a selected W phase that can enhance sputtering performance by a reduction or elimination of nodules in comparison to conventional WTi targets.

The microstructure is further characterized by substantially no β (titanium-tungsten) alloy lamellar phase based on microstructure, as shown in FIG. 6. In another example, the sputtered face of the present invention after 20 kWh is characterized by a cross sectional area whereby no more than 5% of the cross-sectional area contains a β (titanium-tungsten) alloy laminar phase, preferably no more than 3% and more preferably no more than 1%. In another example, the absence of β (titanium-tungsten) alloy laminar phase based on microstructure is defined as the sputter face of the inventive target not containing any precipitated phases of tungsten particles interdiffused within said titanium phase. In yet another example, the absence of β (titanium-tungsten) alloy laminar phase based on microstructure is defined as the sputtering target characterized by a sputtered face in which the interdiffused tungsten particles within a titanium phase does not exceed a predetermined solubility limit of the titanium phase.

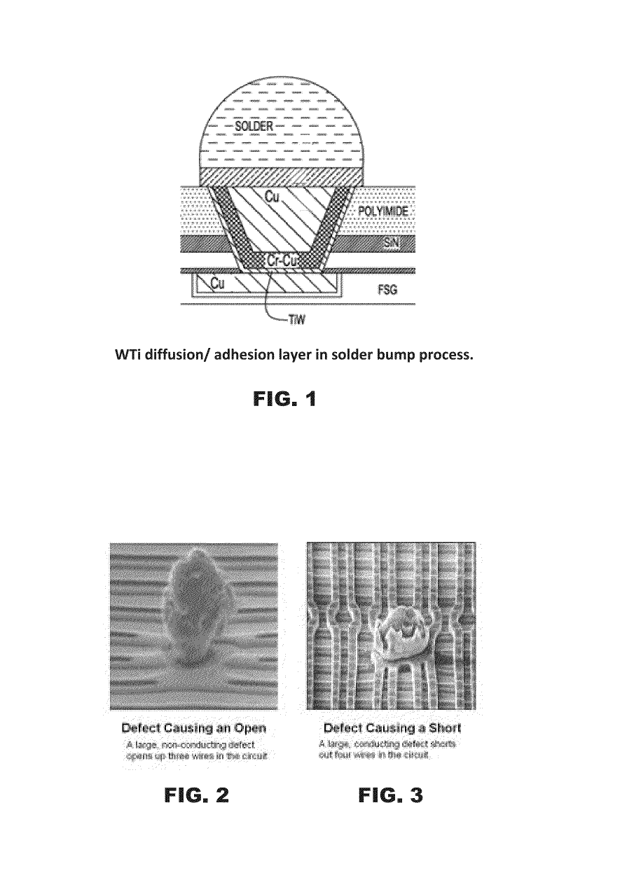

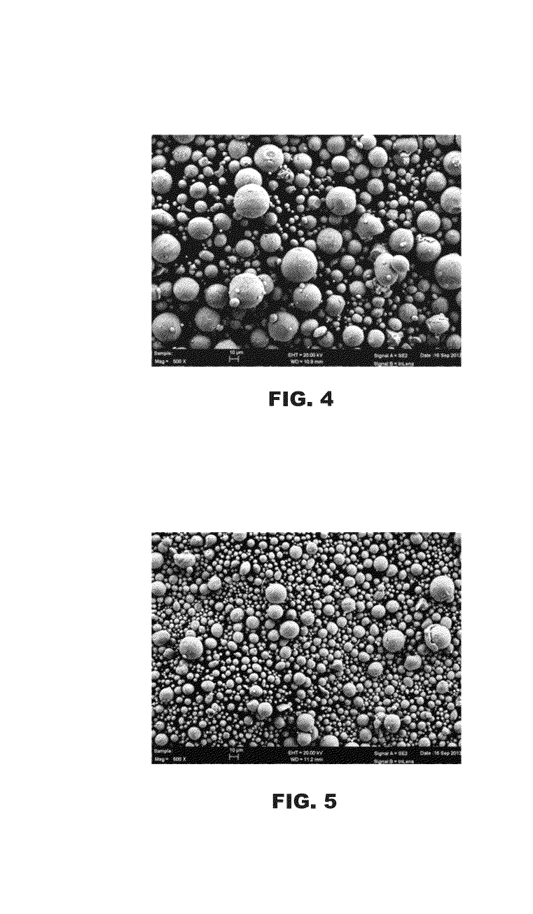

Further, the present invention has a controlled microstructure that is characterized by an absence of interdiffused beta (Ti, W) alloy lamellar phase which is believed to be one of the sources for the formation of particles within the deposited film. The interdiffused beta (Ti, W) alloy lamellar phase is a lamellar phase structure that contains Ti and W intermixed therein. The lamellar phase is brittle and can produce increased particulate emission during sputtering. Additionally, because Ti atoms sputters faster than W atoms, the lamellar structure rapidly becomes depleted of Ti during sputtering, thereby leaving behind only W in the beta (Ti, W) alloy laminar phase. As increasing amounts of Ti atoms are sputtered relative to W atoms, the W atoms no longer have a structural framework to remain attached thereto within the lamellar structure and as a result, the W can be undesirably dislodged from the solidified target material as one or more particles deposited onto the film to produce a defect. Examples of film defects are shown in the scanning electron microscopy (SEMS) of FIG. 2 and FIG. 3.

In order to minimize or eliminate interdiffusion of W into beta (Ti, W) alloy lamellar phase and the film defects resulting therefrom, conventional techniques have utilized larger titanium particles or grains having a particle size ranging from 44 microns up to 1000 microns and more preferred 100-300 microns, as described in U.S. Pat. No. 5,234,487 U.S. Pat. No. 5,234,487 is representative of the prior art which relies on such larger Ti particles to allow for higher amounts of W to interdiffuse therewithin without exceeding the solubility limit of W particles into the Ti-rich phases. The prior art aims to increase Ti particle diameter and volumes to allow higher amounts of W to interdiffuse therewithin without precipitation of W inside the Ti phase to produce brittle beta (Ti, W) alloy lamellar phases.

The present invention, on the contrary, has unexpectedly discovered that significantly smaller Ti grains or particles that closely matches that of W particles can be utilized to avoid formation of W interdiffused into the beta (Ti, W) alloy laminar phase such as, by way of example, a beta (Ti, W) alloy lamellar phase. The particle range is sufficiently small enough to produce a controlled microstructure consisting essentially of a Ti phase and a W phase whereby the Ti phase and the W phase are interdispersed with each other throughout the WTi target structure so that the number of titanium particles per 200 micrometer square unit area of the inventive target prior to sputtering is between about 50 to about 500 particles. In alternative embodiments, the number of Ti particles per a 200 micrometer square unit area of the inventive target prior to sputtering can range between about 100-500 and more preferably 300-500.

Unlike the prior art, the present invention has discovered that Ti size and Ti particle distribution can impact overall sputtering performance. The titanium powder particles are characterized by a predetermined particle size distribution and a median particle size. The tungsten powder particles are also characterized by a particle size distribution and a median particle size. In one embodiment, the titanium and tungsten powder particles are selected such that a difference between their respective median particle sizes of titanium and tungsten is about 15 microns or less.

The titanium and tungsten powder particles are selected such that the W particle range is between about 3-10 microns with a median size of about 7 microns, and the Ti particle range is between about 5-20 microns with a median size of about 15 microns and more preferably about 7-11 microns. Reducing the Ti particle size to a size below 5 microns can increase the surface area of the powder to a degree where unacceptably high oxygen content increases the risk of pyrophoricty. Additionally, increasing the Ti particle size above 20 microns creates particle mismatch between the W particles. Such particle mismatch has been recognized by the present invention to promote formation of nodules along the sputter face during sputtering. Accordingly, the present invention recognizes the benefits of maintaining Ti particle size within a relatively narrow size range that is above a critical minimum and below a critical maximum in order to allow for improved sputtering performance in comparison to conventional TiW targets which typically have particle mismatch or difference between the median sizes of Ti and W that is significantly higher than 15 microns (e.g., 20 microns or more).

In one embodiment, the W and Ti powder particles are selected such that the Ti has a particle size no greater than 20 microns. The Ti powder is not surface treated, such as by hydrogenation, as may be performed in the prior art. Generally speaking, the present invention aims to closely match the particle size of Ti powder particles with that of W powder particles to a degree where median size differences of Ti and W particles is 15 microns or less.

The titanium powder particles may be produced by various suitable processes, such as, atomization processes. In one example, the titanium powder particles are produced by a close coupled atomization process to produce uniform spherical powder particles having acceptable oxygen content and particle size in accordance with the principles of the present invention. In another example, the titanium powder particles are not hydrogenated and derived from an atomization process having oxygen content below 500 ppm.

Because the Ti particle size is selected to closely match that of W to the extent where the difference in their respective median sizes is about 15 microns or less, the present invention offer a counterintuitive shift from conventional WTi targets which utilize Ti powder particles having a larger size distribution, as shown in the SEM of FIG. 4. In a preferred embodiment of the present invention, the Ti powder distribution is significantly narrower and smaller, as shown in the SEM of FIG. 5. In this aspect, the present invention is a significant departure from conventional WTi targets which have relied upon larger Ti powder sizes. Other conventional WTi targets which have utilized smaller Ti grains have not been successful in reducing nodule formation and particle generation to acceptable process levels. Moreover, conventional WTi target structures designed with larger Ti grains than that of the present invention have been observed to exhibit poor sputter performance.

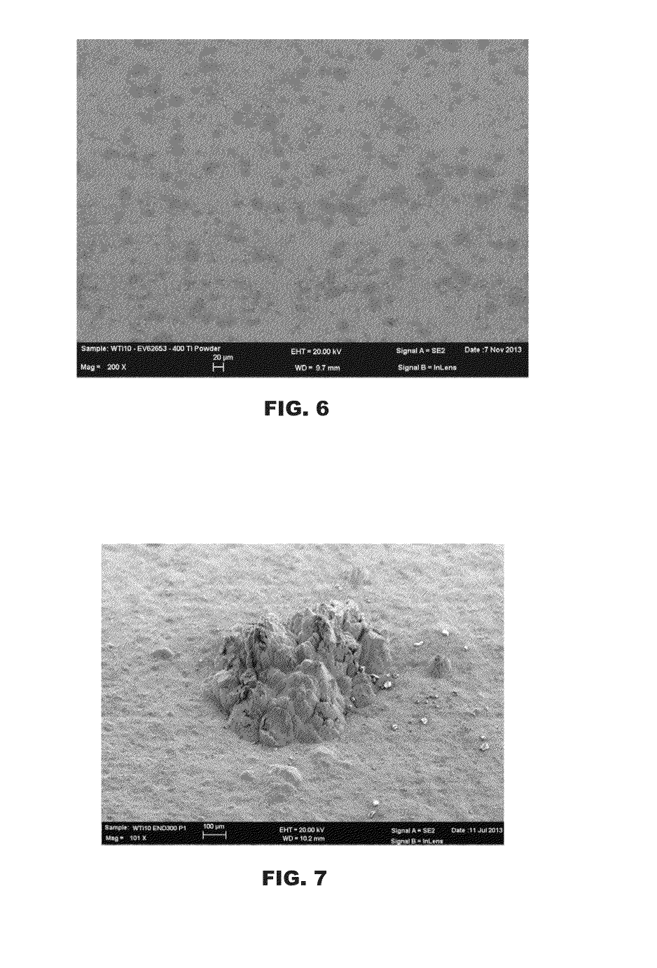

The present invention is unique in that it utilizes a predetermined smaller particle size distribution for Ti powder particles having a size that ranges between a predetermined lower limit and a predetermined upper limit and which approaches that of the W powder particles to create a so-called particle size match that produces a controlled microstructure consisting essentially of a Ti phase and a W phase which is further characterized by an absence or substantial reduction of a beta (Ti, W) alloy lamellar phase structure. In this manner, the present invention offers a unique WTi target structure that can significantly reduce nodule formation on the sputtered target face during sputtering. The sputter face is not roughened during sputtering beyond a critical point at which nucleation would occur to form a significant number of nodules as shown in FIG. 7.

The closely matched size of Ti powder particles and W powder particles produces superior sputtering performance by optimizing the target structure. The present invention creates a target structure that can allow more uniform sputtering. FIG. 6 is an exemplary SEM microstructure of the inventive WTi in accordance with the principles of the present invention. FIG. 6 shows a 600×800 micrometer rectangular area. FIG. 6 shows that the target comprises about 10 wt % Ti and 90% W. The target is shown with a microstructure consisting essentially of a tungsten phase continuously interdispersed with a titanium phase (shown as the darker phase) and substantially no titanium-tungsten alloy lamellar phase. The titanium powder particles are characterized by a particle size distribution ranging from about 5-20 microns and median size of about 15 microns. The tungsten powder particles are characterized by a particle size distribution ranging from about 3-10 microns and a median size of about 7 microns. The number of titanium particles per 200 micrometer square unit area of the target prior to sputtering is about 120. The combination of selected microstructure and a predetermined Ti particle size distribution that is narrower and smaller than conventional Ti particle sizes may facilitate the reduction or elimination of nodule formation on the target surface by the promotion of more uniform sputtering of the Ti and W microstructural phases.

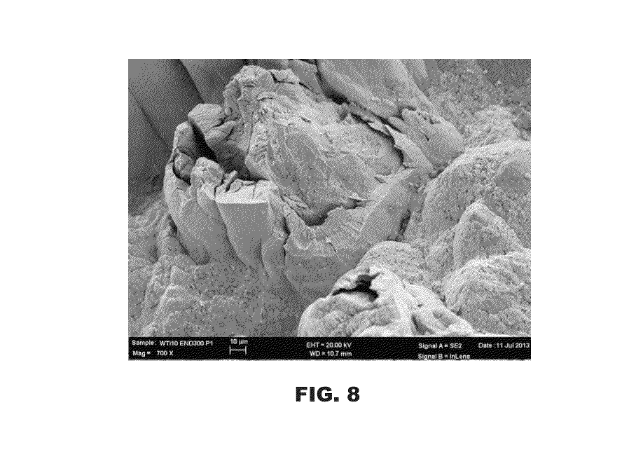

The present invention offers a unique approach for significantly reducing nodule formation on WTi target surfaces by the modified WTi target described herein. The detrimental impact of nodules is well recognized but yet remains prevalent in the industry. Nodules have a tendency to flake from the target surface and thereby generate particles which are subsequently deposited on a sputtered film. These types of in-film particle defects are problematic and significantly decrease material yield. FIG. 7 is a SEM that illustrates a representative nodule that has formed on the TiW sputtered surface of a conventional target. During sputtering, the nodules as shown in FIG. 7 may be formed as a result of nucleation at roughened surfaces of the sputtered target, especially at valleys of the sputtered surface. The roughened surfaces may be produced due to non-uniform sputtering between W and Ti phases of the conventional target. Alternatively, or in addition thereto, the nodules may be formed by one or more other mechanisms. The resulting nodule formation of FIG. 7 can flake off from the target during continued sputtering. The nodules as shown in FIG. 8 have a tendency to deposit onto the film and create in-film particle defects.

The process benefits of the present invention can be attained when the number of Ti particle sizes per 200 micrometer square unit area of the inventive target prior to sputtering is between the prescribed range of about 50 to about 200 particles, preferably 100-500 and more preferably 300-500. Reducing the Ti particle size to an extent where the number of Ti particles per unit area is above 500 can lead to unacceptably high oxygen content in the target and increased risk of pyrophoricty. Additionally, increasing the size of the Ti particles to an extent where the number of titanium particles per 200 micrometer square unit area of the inventive target prior to sputtering is below about 50 may cause non-uniform sputtering and significantly increased nodule formation during sputtering of the WTi target.

Furthermore, the favorable barrier properties of the WTi thin film are optimized when the composition of the inventive target is between about 5-15 wt % Ti and the remainder W. In a preferred embodiment, the titanium comprises about 7-12 wt % and the remainder W. The density is preferably greater than about 98% to produce a substantially non-porous target structure that is not susceptible to particle generation.

The present invention can be utilized for various applications, including by way of example, semiconductor applications and solar panel applications. The inventive target can be formed from any purity level of tungsten and titanium. In a preferred embodiment, the purity level of titanium is 99.99 wt % or greater, and the purity level of tungsten is 99.995 wt % or greater.

The WTi target may be formed by hot pressing, such as vacuum hot pressing or inert gas hot pressing, at suitable processing conditions utilizing the Ti and W powder particles in accordance with the principles of the present invention. The hot press temperature can range from about 1000-1300 C and the hot press pressure can range from about 0.5-2 ksi. Temperatures beyond this are avoided during hot pressing to avoid formation of various brittle phases, including, a β (titanium-tungsten) alloy lamellar phase. The temperature and pressure are maintained for a duration ranging from about 1-10 hours. Heat treatment is not performed to minimize or eliminate many of the titanium-tungsten alloy phases, including the β (titanium-tungsten) alloy lamellar phase. Ball milling, pulverizing or other similar types of particle size reduction processes are avoided. It should be understood that the inventive target can also be produced utilizing other conventional processes, including, by way of example, hot isostatic pressing procedures (HIP′ing) as generally known in the industry. The oxygen content in the resultant target that is formed is sufficiently low so as to not contaminant or adversely impact the target properties. In one embodiment, the oxygen in the target is about 1500 ppm or lower, and more preferably 500 ppm or lower.

The WTi target of the present invention is configured to be sputtered to form a sputter face having significantly lower roughness and significantly reduced formation of nodules in comparison to a conventional WTi sputter having about 5-15 titanium particles per 200 micrometer square unit area. The roughness of the sputtered surface (designated herein as “Ra”) of the inventive target is less than 200 microinches, preferably less than 150 microinches, and more preferably less than 100 microinches. In another embodiment, the average Ra of a sputter surface is 150 microinches or less, preferably 100 microinches or less and more preferably 75 microinches or less. The Ra can serve as one indicator of the formation of nodules along a sputtered surface of the target. Unlike conventional WTi targets, the present invention can reduce or eliminate formation of nodules and the beta (Ti, W) alloy laminar phase, both of which are precursors or sources for particle generation in deposited films produced during sputtering. The ability to reduce or eliminate beta (Ti, W) alloy laminar phase without utilizing larger Ti particles is a counterintuitive approach that is unique to the present invention. Further, the present invention has discovered nodules, which have a tendency to flake off from the sputter face onto the film as a particle defect, can be reduced or eliminated by close particle size matching of the W and Ti particles as described herein. The resultant film that is sputtered exhibits reduced film defects as a result of particle generation, by virtue of elimination or substantial reduction of both precipitation of the beta (Ti, W) alloy laminar phase and formation of nodules. As a result, the present invention offers an improved and substantially modified target designed to substantially increase material yield and throughput (e.g., number of devices produced per wafer) in comparison to conventional WTi targets as well as longer target lifetime.

### Comparative Example 1

A conventional 11.5 inch diameter planar target assembly was fabricated having a thickness of 0.25 inches and a composition of 10 wt % titanium and the balance tungsten. The target was formulated from titanium powder particles and tungsten powder particles. The titanium powder had a purity of 99.99 wt % and was obtained from Sumitomo (Japan). The titanium powder particles had a particle size distribution ranging from 5-45 microns with a median size of 25 microns. The tungsten powder had a purity of 99.995 wt % and was obtained from H.C. Starck (Germany). The tungsten powder particles had a particle size distribution ranging from 3-10 microns with a median size of 7 microns. The titanium and tungsten powder particles were consolidated to form a solidified target by vacuum hot pressing. Vacuum hot pressing was performed at a temperature of 1270 C and a sintering pressure of 1 ksi for 5 hours. The beta (Ti, W) alloy laminar phase was not observed based on microstructure. After vacuum hot pressing, the resultant solidified target was bonded to a copper backing plate. The target density was nearly theoretical density at 14.53 grams/cc.

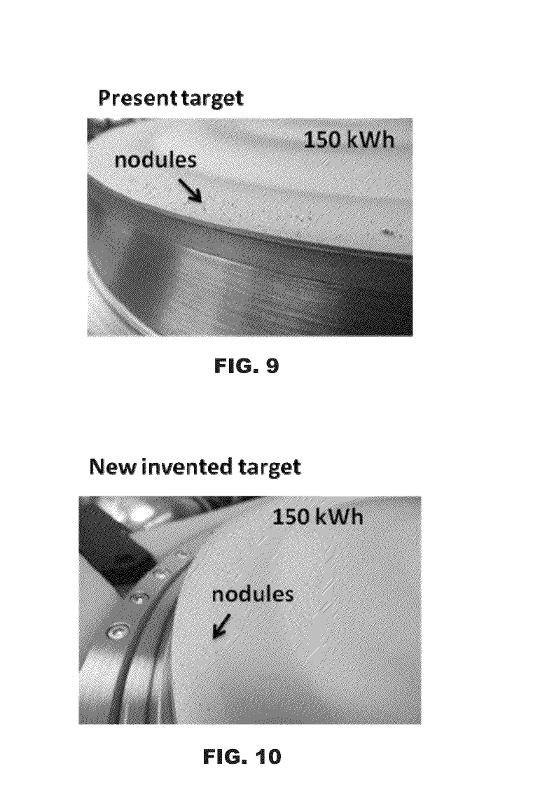

The target assembly was sputtered in an Endura® Model 150 sputtering tool commercially available from Applied Materials (Santa Clara, Calif.). The target was sputtered by applying 5.5 kW of power and a flow rate of 60 sccm Argon gas. The sputtering was stopped after 150 kWh to evaluate the appearance of the sputtered target surface. An abundance of nodules (seen as black dots as indicated by the arrow) were observed, particularly along the periphery of the sputtered target face, as shown in FIG. 9. The morphology of the nodule was observed as shown in FIGS. 7 and 8 by scanning electron microscopy. The irregularities along the top portion of the nodule suggests a portion of the nodule dislodged or flaked from the target surface during sputtering, fallen towards the film and deposited thereon to create in-film particle defects.

The surface roughness Ra of the sputtered target surface shown in FIG. 9 was measured at various locations along the sputtered surface to have a variation ranging from 96-120 μ-in. The average Ra was determined to be 106 μ-in. A profilometer known as a Mahr Federal Pocket Surf was utilized to measure the surface roughness.

### Example 1

A planar target assembly according to the present invention was fabricated. The target had a diameter of 11.5 inches and diameter of 0.25 inches. The target composition was 10 wt % titanium and the balance tungsten. The target was formulated from titanium powder particles and tungsten powder particles. The titanium powder had a purity of 99.99 wt % and was obtained from Sumitomo (Japan). The titanium powder particles were screened using a 400 mesh sieve to create particle size distribution ranging from 5-20 microns with a median size of 15 microns. The tungsten powder had a purity of 99.995 wt % and was obtained from H.C. Starck (Germany). The tungsten powder particles had a particle size distribution ranging from 3-10 microns with a median size of 7 microns. The titanium and tungsten powder particles were consolidated to form a solidified target by vacuum hot pressing. Vacuum hot pressing was performed at a temperature of 1270 C and a sintering pressure of 1 ksi for 5 hours. The beta (Ti, W) alloy laminar phase was not observed based on microstructure as shown in FIG. 6. After vacuum hot pressing, the resultant solidified target was bonded to a copper backing plate. The target density was nearly theoretical density at 14.53 grams/cc.

The target assembly was sputtered in an Endura® Model 150 sputtering tool commercially available from Applied Materials (Santa Clara, Calif.). The target was sputtered by applying 5.5 kW of power and a flow rate of 60 sccm Argon gas. The sputtering was stopped after 150 kWh to evaluate the appearance of the sputtered target surface, as shown in FIG. 10. FIG. 10 shows a significant reduction in nodules observed in comparison to that FIG. 9. The amount of nodules observed in FIG. 9 was approximately 3 times more than that observed in FIG. 10. The substantial reduction in nodules in Figure suggests less in-film particle defects.

The surface roughness Ra of the sputtered target surface shown in FIG. 10 was measured at various locations along the sputtered surface to have a variation ranging from 55-88 μ-in. The average Ra was determined to be 73 μ-in. A profilometer known as a Mahr Federal Pocket Surf was utilized to measure the surface roughness.

While it has been shown and described what is considered to be certain embodiments of the invention, it will, of course, be understood that various modifications and changes in form or detail can readily be made without departing from the spirit and scope of the invention. It is, therefore, intended that this invention not be limited to the exact form and detail herein shown and described, nor to anything less than the whole of the invention herein disclosed and hereinafter claimed.

1. A sputtering target comprising:
a solidified target comprising consolidated titanium particles in a composition ranging between about 5-15 wt % and a balance of consolidated tungsten, said target having a microstructure consisting essentially of a tungsten phase interdispersed with a titanium phase and further characterized by substantially no β (titanium-tungsten) alloy lamellar phase based on microstructure;
said titanium powder particles characterized by a first particle size distribution having a particle size no greater than 20 microns, and said tungsten powder particles characterized by a second particle size distribution, wherein the first particle size is matched to the second particle size such that a difference between a median particle size of the titanium particles and a median particle size of the tungsten particles is about 15 microns or less;
wherein said target is characterized by a substantial reduction or absence of nodule formation visually observed during sputtering in comparison to a conventional consolidated tungsten-titanium target without particle size matching.

2. The sputtering target of claim 1, wherein said microstructure is further characterized by an absence of W interdiffused into a beta (Ti, W) phase.

3. The sputtering target of claim 1, wherein said titanium has a first median particle size and said tungsten has a second median particle size, said difference between the first and second median particles sizes being no greater than about 7-11 microns.

4. The sputtering target of claim 1, wherein said difference between the median particle size of titanium and the median particle size of tungsten is about 5 microns or less.

5. The sputtering target of claim 1, wherein said titanium particles comprises about 7-12 wt % based on the weight of the target, and further wherein said titanium particles comprises a purity level of 99.9 wt % or higher.

6. The sputtering target of claim 1, wherein said oxygen content is about 1500 ppm or lower.

7. A titanium-tungsten sputtering target configured to be sputtered to produce improved titanium-tungsten films having reduced in-film particle defects, comprising:
a solidified target comprising consolidated titanium powder particles in a compositional range of said target between about 5-15 wt % titanium based on a total weight of the solidified target and a balance of consolidated tungsten powder particles, said target having a microstructure consisting essentially of a tungsten phase continuously interdispersed with a titanium phase and further characterized by substantially no β (titanium-tungsten) alloy lamellar phase based on microstructure;
said titanium powder particles characterized by a first particle size distribution having a first median size and further wherein the number of titanium particles per 200 micrometer square unit area of the target prior to sputtering is between about 50 to about 200;
said tungsten powder particles characterized by a second particle size distribution having a second median size, the first particle size distribution matched with the second particle size distribution such that a difference between the first and the second median particle sizes is about 15 microns or less.

8. The sputtering target of claim 7, wherein said tungsten powder particles has a particle size ranging from 3-10 micrometers.

9. The sputtering target of claim 7, wherein said target is configured to be sputtered to form a sputter face having a reduced formation of nodules in comparison to a conventional WTi sputter not having particle size matching of Ti with W.

10. The sputtering target of claim 1, wherein said target is configured to be sputtered to form a sputter face having a lower surface roughness (Ra) in comparison to a conventional WTi not having particle size matching of Ti with W.

11. A WTi film produced by the target of claim 1, said film characterized by a reduction or elimination of particle defects contained therein in comparison to a film produced by a conventional WTi not having particle size matching of Ti with W.

12. The sputtering target of claim 1, further comprising a density greater than about 98%.

13. A sputtering target comprising:
a solidified target comprising consolidated titanium particles in a compositional range of said target between about 5-15 wt % based on a total weight of the solidified target, and a balance of consolidated tungsten powder particles, said target having a titanium characterized by the absence of hydrogenation;
said solidified target having a multi-phase microstructure consisting essentially of a tungsten phase continuously interdispersed with a titanium phase, wherein said multi-phase microstructure is further characterized by substantially no β (titanium-tungsten) alloy laminar phase based on microstructure,
said titanium powder particles characterized by a first particle size distribution of 5-20 microns and said tungsten powder particles characterized by a second particle size distribution of 3-10 microns, wherein the titanium powder particles are matched with the tungsten powder particles to a degree such that a difference between a median particle size of titanium and a median particle size of tungsten is about 15 microns or less;
wherein said target is configured to be sputtered so as to form a sputter target face having a substantial reduction or elimination of nodules visually observed during sputtering in comparison to a conventional titanium-tungsten sputtering target without particle size matching, thereby reducing or eliminating particle generation onto TiW films produced from sputtering said sputtering target.

14. The sputtering target of claim 13, further characterized by an average surface roughness (Ra) along the sputtered face of the target of no greater than about 100 microinches (μ-in) after 20 kWh of sputtering.

15. The sputtering target of claim 13, wherein said titanium powder particles have a size no greater than 20 microns and further wherein said titanium powder particles comprises a titanium purity level of 99.9 wt % or higher.

16. The sputtering target of claim 13, wherein said sputtered face after 20 kWh is characterized by a cross sectional area whereby no more than 5% of the cross-sectional area contains a β (titanium-tungsten) alloy laminar phase.

17. The sputtering target of claim 13, wherein said oxygen content is 1500 ppm or lower.

18. The sputtering target of claim 13, wherein said titanium powder particles is not hydrogenated and derived from an atomization process having oxygen content below 500 ppm.

19. The sputtering target of claim 13, said absence of β (titanium-tungsten) alloy laminar phase based on microstructure is defined as said target not containing any precipitated phases of tungsten particles interdiffused within said titanium phase.

20. The sputtering target of claim 13, wherein said interdiffused tungsten particles within said titanium phase does not exceed a predetermined solubility limit of said titanium phase.
